(19) United States
(12) Patent Application Publication
(10) Pub. No.: US 2026/0214991 A1
(43) Pub. Date: Jul. 23, 2026

(54) DISPLAY PANEL, DISPLAY APPARATUS, AND METHOD FOR MANUFACTURING DISPLAY PANEL

(71) Applicant: Xiamen Tianma Optoelectronics Co., Ltd., Xiamen (CN)

(72) Inventors: Zongcai DING, Xiamen (CN); Xuhui PENG, Xiamen (CN); Youdao LIN, Xiamen (CN); Xiaohe LI, Xiamen (CN); Tianci LI, Xiamen (CN); Qiongqin MAO, Xiamen (CN)

(73) Assignee: Xiamen Tianma Optoelectronics Co., Ltd., Xiamen (CN)

(21) Appl. No.: 19/242,926

(22) Filed: Jun. 18, 2025

(30) Foreign Application Priority Data
Jan. 17, 2025 (CN) 202510080351.6

(51) Int. Cl. H10D 86/60; G02F 1/1333

(52) U.S. Cl. CPC H10D 86/60; G02F 1/13338

(57) ABSTRACT

The present application provides a display panel, a display apparatus, and a method for manufacturing a display panel. The display panel includes opening areas and a non-opening area and further includes: a substrate; a first insulation layer disposed on a side of the substrate, wherein the first insulation layer has hollow areas and a non-hollow area, the hollow area is disposed at a side of the non-hollow area, the hollow areas at least partially overlap the opening areas respectively, and a material of the first insulation layer is an inorganic material; and a second insulation layer disposed in the hollow area and the non-hollow area, wherein a material of the second insulation layer is an organic material, and a thickness of part of the second insulation layer within the non-hollow area is smaller than a thickness of part of the second insulation layer within the hollow area.

### CROSS REFERENCE TO RELATED APPLICATION

The present application claims priority to Chinese Patent Application No. 202510080351.6 filed on Jan. 17, 2025, which is incorporated herein by reference in its entirety.

### TECHNICAL FIELD

The present application relates to the technical field of display technology, and in particular to a display panel, a display apparatus, and a method for manufacturing a display panel.

### BACKGROUND

Thin Film Transistor-Liquid Crystal Display (TFT-LCD) is a display technology that combines thin film transistor and liquid crystal display technology. It is provided with a thin film transistor on each pixel, which allows each pixel to be independently controlled, thereby overcoming the crosstalk during a non-gated state, and improving the display quality.

### SUMMARY

In an aspect, the present application provides a display panel comprising opening areas and a non-opening area, and the display panel further comprises: a substrate; a first insulation layer disposed on the side of the substrate, wherein the first insulation layer has hollow areas and a non-hollow area, the hollow area is disposed at the side of the non-hollow area, the hollow areas at least partially overlap the opening areas respectively, and a material of the first insulation layer is an inorganic material; a second insulation layer overlapping the hollow area and the non-hollow area, wherein a material of the second insulation layer is an organic material, and a thickness of part of the second insulation layer overlapping the non-hollow area is smaller than a thickness of part of the second insulation layer overlapping the hollow area.

In another aspect, the present application provides a display apparatus comprising any one of the display panels.

In still another aspect, the present application provides a method for manufacturing a display panel comprising opening areas and a non-opening area, and the method comprises: providing a substrate; forming a first preliminary insulation layer on the side of the substrate, wherein a material of the first preliminary insulation layer is an inorganic material; removing part of the first preliminary insulation layer, and forming a first insulation layer having hollow areas and a non-hollow area from the remaining first preliminary insulation layer, the hollow area at least partially overlapping the opening area; forming a second insulation layer overlapping the hollow area and the non-hollow area, a material of the second insulation layer being an organic material.

### BRIEF DESCRIPTION OF THE DRAWINGS

Accompanying drawings constituting a part of the present application are used for a further understanding of the present application. Illustrative embodiments of the present application and description thereof are used for explaining the present application and do not improperly limit the present application. In the accompanying drawings:

FIG. 1 shows a schematic structural view of a display panel according to embodiments of the present application;

FIG. 2 shows a schematic structural view of a display panel according to embodiments of the present application;

FIG. 3 shows a schematic structural view of another display panel according to embodiments of the present application;

FIG. 4 shows a schematic structural view of still another display panel according to embodiments of the present application;

FIG. 5 shows a schematic structural view of a display panel according to embodiments of the present application;

FIG. 6 shows a schematic structural view of a display panel according to embodiments of the present application;

FIG. 7 shows a schematic structural view of another display panel according to embodiments of the present application;

FIG. 8 shows a schematic structural view of a display panel according to embodiments of the present application;

FIG. 9 shows a schematic structural view of a display panel according to embodiments of the present application;

FIG. 10 shows a schematic structural view of another display panel according to embodiments of the present application;

FIG. 11 shows a schematic structural view of still another display panel according to embodiments of the present application;

FIG. 12 shows a schematic structural view of a display panel according to embodiments of the present application;

FIG. 13 shows a schematic structural view of another display panel according to embodiments of the present application;

FIG. 14 shows a schematic structural view of still another display panel according to embodiments of the present application;

FIG. 15 shows a schematic structural view of still another display panel according to embodiments of the present application;

FIG. 16 shows a schematic structural view of a display panel according to embodiments of the present application;

FIG. 17 shows a schematic structural view of another display panel according to embodiments of the present application;

FIG. 18 shows a schematic structural view of still another display panel according to embodiments of the present application;

FIG. 19 shows a schematic structural view of a display panel according to embodiments of the present application;

FIG. 20 shows a schematic structural view of another display panel according to embodiments of the present application;

FIG. 21 shows a schematic structural view of still another display panel according to embodiments of the present application;

FIG. 22 shows a schematic structural view of still another display panel according to embodiments of the present application;

FIG. 23 shows a schematic structural view of a display panel according to embodiments of the present application;

FIG. 24 shows a flowchart of a method for manufacturing a display panel according to embodiments of the present application;

FIG. 25 shows a schematic structural view corresponding to each step in the method for manufacturing a display panel according to embodiments of the present application;

FIG. 26 shows a flowchart of step S1011 in the method for manufacturing a display panel according to embodiments of the present application;

FIG. 27 shows a flowchart of step S1031 in the method for manufacturing a display panel according to embodiments of the present application; and

FIG. 28 shows a flowchart of step S1032 in the method for manufacturing a display panel according to embodiments of the present application.

The above accompanying drawings include the following reference signs:
01, Display area; 02, non-display area; 10, opening area; 11. non-opening area; 12, substrate; 13, first insulation layer; 131, hollow area; 132, non-hollow area; 14, second insulation layer; 141, first sub-insulation layer; 142, second sub-insulation layer; 15, third insulation layer; 16, fourth insulation layer; 17, fifth insulation layer; 18, touch signal line; 19, sixth insulation layer; 20, common electrode layer; 21, seventh insulation layer; 22, eighth insulation layer; 23, ninth insulation layer; 24, thin film transistor; 241, gate electrode; 242, active layer; 243, source electrode; 244, drain electrode; 25, tenth insulation layer; 26, pixel electrode layer; 30, first preliminary insulation layer; 100, display panel.

### DETAILED DESCRIPTION

It should be noted that, the embodiments and features in the embodiments of the present application may be combined with each other as long as there is no conflict. The present application will be described in detail below with reference to the specific embodiments and the drawings.

In order to enable those skilled in the art to better understand the solutions of the present application, the technical solutions in the embodiments of the present application will be clearly and completely described below with reference to the accompanying drawings in the embodiments of the present application, and it is obvious that the described embodiments are only some embodiments of the present application, but not all embodiments. Based on the embodiments in the present application, all other embodiments obtained by those skilled in the art without inventive effort should belong to the scope of protection of the present application.

It should be noted that the terms “first”, “second” and the like in the description, claims and the above description of the accompanying drawings of the present application are used for distinguishing similar objects, and not necessarily for describing a specific order or priority in order. It should be understood that the data used in this manner is interchangeable under appropriate conditions, so that the embodiments of the present application described herein can be implemented in other orders than illustrated or described herein. Moreover, the terms “comprising” and “including”, as well as any variation thereof, are intended to cover a non-exclusive inclusion. For example, a series of steps or units included in a process, a method, a system, a product, or a device are not limited to the steps or units that are listed expressly, but may include other steps or units that are not listed expressly or are inherently included in a process, a method, a system, a product, or a device.

As described in the background, the transmittance of a display panel in the prior art is poor, and to solve the above-described technical problem, the present application provides a display panel, a display apparatus, and a method for manufacturing a display panel.

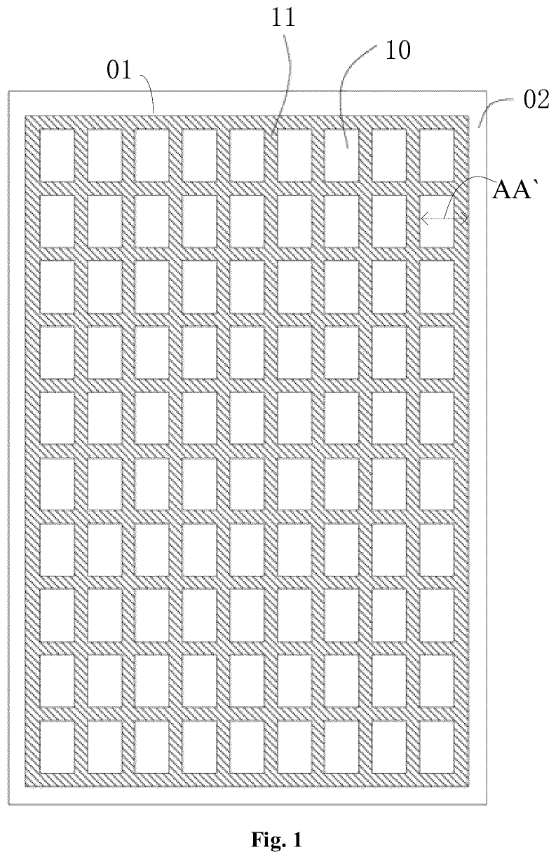

FIG. 1 shows a top view of a display panel according to embodiments of the present application, and as shown in FIG. 1, the display panel comprises a portion corresponding to a display area 01 and a portion corresponding to a non-display area 02, wherein the display area 01 is an area for displaying images on the display panel, and the non-display area 02 is a bezel area surrounded by the area for displaying images on the display panel. The display area 01 comprises opening areas 10 arranged in an array and a non-opening area 11 disposed outside the opening areas 10.

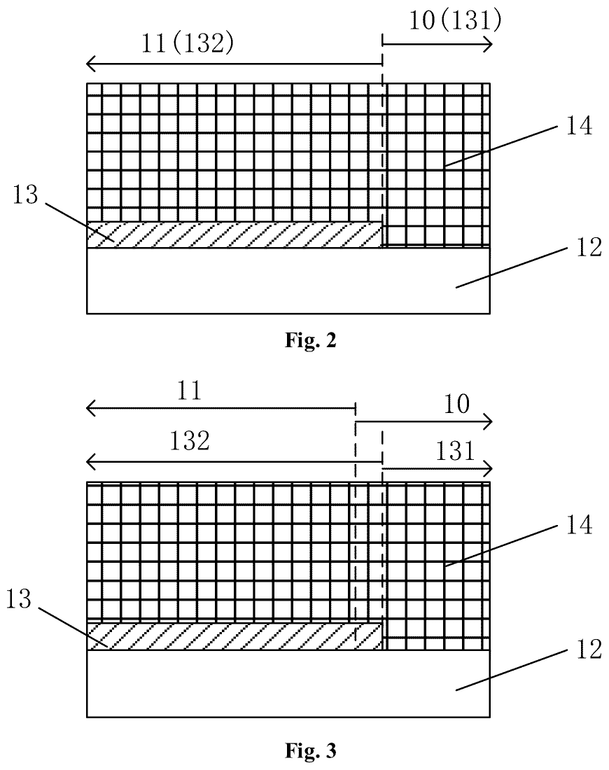

FIG. 2 shows a cross-sectional view along the direction AA′ in FIG. 1. As shown in FIGS. 2 to 14, the display panel comprises opening areas 10 and a non-opening area 11, and the display panel comprises:
a substrate 12, a first insulation layer 13, and a second insulation layer 14.

Specifically, in the display panel, the opening areas 10 may be arranged in an array, and the non-opening area 11 may be disposed outside the opening areas 10. In practical applications, one of the above-described opening areas 10 corresponds to a sub-pixel, and the sub-pixel is displayed through the corresponding opening area 10.

The first insulation layer 13 is disposed on a side of the substrate 12, and the first insulation layer 13 has hollow areas 131 and a non-hollow area 132, the hollow area 131 is disposed at a side of the non-hollow area 132, the hollow area 131 at least partially overlaps the opening area 10, and the material of the first insulation layer 13 is an inorganic material.

Specifically, the first insulation layer 13 may have a single-layer structure or a multilayer structure. It should be noted that the thickness of the first insulation layer 13 overlapping the non-hollow area 132 is larger than the thickness of that overlapping the hollow area 131, i.e., the thickness of the first insulation layer overlapping the non-hollow area 132 is not 0, and the thickness of the first insulation layer 13 in the hollow area 131 is 0. The above-described non-hollow area 132 may at least partially overlap the non-opening area 11. In practical applications, as shown in FIG. 2, the hollow area 131 may completely overlap the opening area 10; and as shown in FIG. 3, the hollow area 131 may partially overlap the opening area 10, or the non-hollow area 132 may partially overlap the non-opening area 11. The first insulation layer 13 may be made of any kind of inorganic insulation material, and the material type of the first insulation layer 13 is not limited in the present application.

The second insulation layer 14 overlaps the hollow area 131 and the non-hollow area 132, the material of the second insulation layer 14 is an organic material, and the thickness of the second insulation layer 14 overlapping the non-hollow area 132 is smaller than the thickness of the second insulation layer 14 overlapping the hollow area 131.

Embodiments of the present application provide a display panel, in which the structures of a portion corresponding to opening areas and a portion corresponding to a non-opening area in the display panel are separately designed, the opening areas correspond to hollow areas of the first insulation layer, and the second insulation layer is arranged in the hollow area, and due to the material of the first insulation layer is an inorganic material, it can be formed by chemical deposition, and due to the material of the second insulation layer is an organic material, it can be formed by coating. The organic material is used to replace the original inorganic material. Due to the leveling characteristics of the organic material, it can make the surface of the second insulation layer away from the substrate overlapping the hollow area as flush with that overlapping the non-hollow area as possible, thereby reducing the number of optical interfaces in the opening area. In addition, since the non-opening area corresponds to the non-hollow area of the first insulation layer, the reflectivity is reduced without affecting the original film layer structure of the non-opening area of the display panel, and the transmittance of the display panel is improved, thereby solving the technical problem with how to increase the transmittance of the display panel in the prior art.

In another specific embodiment, as shown in FIGS. 2 and 3, the second insulation layer 14 is disposed above the side of the first insulation layer 13 away from the substrate 12. The surface of the portion, overlapping the hollow area 131, of the second insulation layer 14 away from the substrate 12 may be flush with the surface of the portion, overlapping the non-hollow area 132, of the second insulation layer 14 away from the substrate 12. The specific position of the second insulation layer 14 described above can simultaneously form the portion of the second insulation layer 14 overlapping the hollow area 131 and the portion of the second insulation layer 14 overlapping the non-hollow area 132 simultaneously in a process step, further reducing the process flow and saving the manufacturing time of the display panel.

Specifically, the formation process of the display panel including the second insulation layer is as follows: providing a substrate; forming a first preliminary insulation layer on the surface of the side of the substrate; removing part of the first preliminary insulation layer to form hollow areas, and forming a first insulation layer with the remaining first preliminary insulation layer to obtain a first preliminary structure; and forming a second insulation layer on the exposed surface of the first preliminary structure.

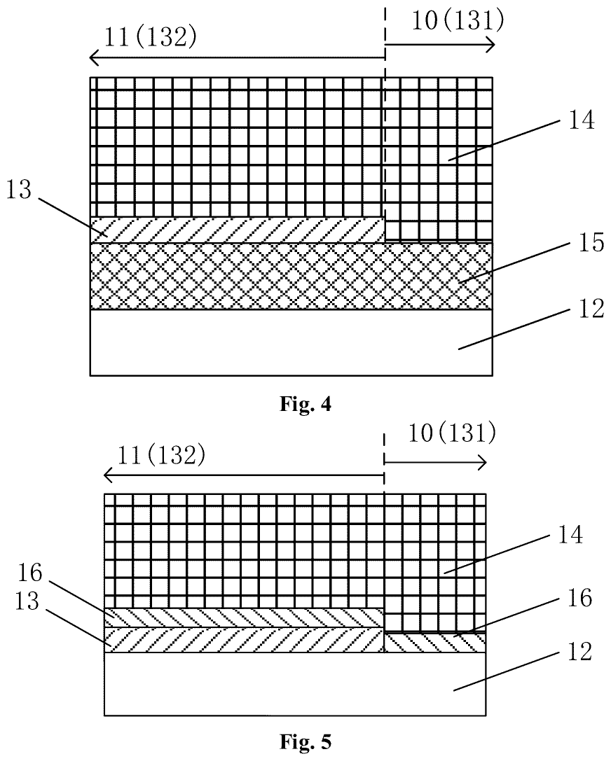

In another specific embodiment, as shown in FIG. 4, the display panel further includes a third insulation layer 15 overlapping the hollow area 131 and the non-hollow area 132, and the thickness of the third insulation layer 15 overlapping the hollow area 131 may be equal or unequal to the thickness of the third insulation layer 15 overlapping the non-hollow area 132. In addition, the third insulation layer 15 is disposed between the substrate 12 and the second insulation layer 14 and between the substrate 12 and the first insulation layer 13. The third insulation layer 15 described above can serve as a buffer layer of the display panel to alleviate stress caused by the lattice constant mismatch between the substrate 12 and the first insulation layer 13 or the second insulation layer 14, thereby further improving the performance of the display panel.

Specifically, the formation process of the display panel including the third insulation layer is as follows: providing a substrate; forming a third insulation layer on the surface of the side of the substrate; forming a first preliminary insulation layer on the surface of the third insulation layer away from the substrate; removing the part of the first preliminary insulation layer to form hollow areas, and forming a first insulation layer with the remaining first preliminary insulation layer to obtain a second preliminary structure; and forming a second insulation layer on the exposed surface of the second preliminary structure.

To further improve the transmittance of the display panel, the material of the third insulation layer is different from the material of the second insulation layer. Since the material of the second insulation layer is an organic material, the material of the third insulation layer may be an inorganic material.

Specifically, the third insulation layer may be made of at least one of silicon oxide or silicon nitride.

In another specific embodiment, the material of the third insulation layer is silicon nitride. The buffer layer in the prior art is generally a double-layer or multi-layer structure made of silicon nitride and silicon oxide. Since the refractive index of the silicon nitride layer is different from that of the silicon oxide layer, reflection occurs at the interface of the silicon nitride layer and the silicon oxide layer, so that the light loss is relatively large when light passes through the interface of the silicon nitride layer and the silicon oxide layer, and thus the transmittance of the opening area is reduced. That is, by removing silicon oxide on the basis of the prior art, the material of the third insulation layer is silicon nitride, and the transmittance of the opening area can be further improved.

As shown in FIG. 5, the display panel further includes a fourth insulation layer 16 overlapping the hollow area 131 and the non-hollow area 132, and the thickness of the part of the fourth insulation layer 16 overlapping the hollow area 131 may be equal or unequal to the thickness of the part of the fourth insulation layer 16 overlapping the non-hollow area 132. The fourth insulation layer 16 is disposed between the substrate 12 and the second insulation layer 14. The fourth insulation layer 16 described above can serve as an interlayer insulation layer of the display panel to achieve insulation between metals inside devices and reduce parasitic capacitance between the metal material and the substrate, thereby further improving the performance of the display panel.

In practical applications, the part of the fourth insulation layer overlapping the hollow area and the part of the fourth insulation layer overlapping the non-hollow area may be formed synchronously, or may be formed separately. The formation process of the display panel including the fourth insulation layer is as follows: providing a substrate; forming a first preliminary insulation layer on the surface of the side of the substrate; removing part of the first preliminary insulation layer to form hollow areas, and forming a first insulation layer from the remaining first preliminary insulation layer to obtain a third preliminary structure; and forming a fourth insulation layer on the exposed surface of the third preliminary structure.

In another specific embodiment, the material of the fourth insulation layer is different from the material of the second insulation layer. Since the material of the second insulation layer is an organic material, the material of the fourth insulation layer may be an inorganic material.

Specifically, the fourth insulation layer is made of at least one of silicon oxide or silicon nitride.

In another specific embodiment, the material of the fourth insulation layer is silicon nitride. The interlayer insulation layer in the prior art is generally a double-layer or multi-layer structure made of silicon nitride and silicon oxide, and since the refractive index of the silicon nitride layer is different from that of the silicon oxide layer, and thus reflection occurs at the interface of the silicon nitride layer and the silicon oxide layer, so that the light loss is relatively large when light passes through the interface between the silicon nitride layer and the silicon oxide layer, and thus the transmittance of the opening area is reduced. That is, by removing the silicon oxide on the basis of the prior art, the material of the fourth insulation layer is silicon nitride, and the transmittance of the opening area can be further improved.

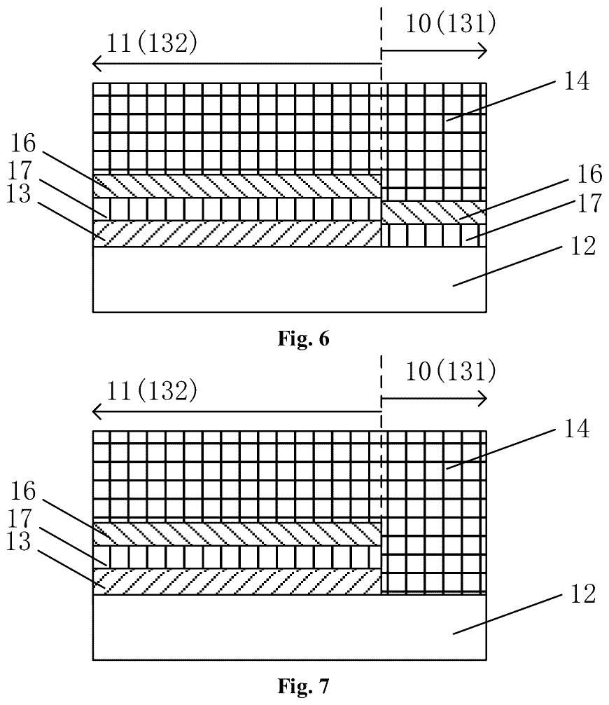

In another specific embodiment, as shown in FIG. 6, the display panel further includes a fifth insulation layer 17 overlapping the hollow area 131 and the non-hollow area 132, and the thickness of the fifth insulation layer 17 overlapping the hollow area 131 may be equal or unequal to the thickness of the fifth insulation layer 17 overlapping the non-hollow area 132. The fifth insulation layer 17 is disposed between the substrate 12 and the fourth insulation layer 16. The fifth insulation layer 17 described above can serve as an interlayer insulation layer of the display panel to ensure insulation between metals inside devices and reduce parasitic capacitance between the metal material and the substrate, thereby further improving the performance of the display panel.

In practical applications, the part of the fifth insulation layer overlapping the hollow area and the part of the fifth insulation layer overlapping the hollow area may be formed synchronously, or may be formed separately. The formation process of the display panel including the fourth insulation layer and the fifth insulation layer is as follows: providing a substrate; forming a first preliminary insulation layer on the surface of the side of the substrate; removing the part of the first preliminary insulation layer to form hollow areas, and forming a first insulation layer from the remaining first preliminary insulation layer to obtain a third preliminary structure; and sequentially forming a fourth insulation layer and a fifth insulation layer on the exposed surface of the third preliminary structure.

To further improve the stability of the display panel, the material of the fifth insulation layer is different from the material of the second insulation layer. The material of the fifth insulation layer may be an inorganic material.

Specifically, the fifth insulation layer may be made of at least one of silicon oxide or silicon nitride.

In another specific embodiment, the material of the fifth insulation layer is silicon oxide. By using silicon oxide and silicon nitride as the interlayer insulation layer, the stability of the interlayer insulation layer can be further improved.

In another embodiment, as shown in FIG. 7, the display panel includes a substrate 12, a first insulation layer 13, a fifth insulation layer 17, a fourth insulation layer 16, and a second insulation layer 14 that are stacked in sequence, wherein the first insulation layer 13, the fourth insulation layer 16, and the fifth insulation layer 17 are overlapping the non-hollow area 132, and the second insulation layer 14 overlaps the hollow area 131 and the non-hollow area 132. That is, after the fourth insulation layer 16 and the fifth insulation layer 17 are formed, the portion corresponding to the hollow area 131 is removed. The reflection interface of the opening area of the display panel can be further reduced, thereby further improving the transmittance of the display panel, that is, the interface reflection between the first insulation layer 13 and the fifth insulation layer 17, the interface reflection between the fifth insulation layer 17 and the fourth insulation layer 16, and the interface reflection between the fourth insulation layer 16 and the second insulation layer 14 can be reduced.

As shown in FIGS. 2 to 14, the difference between the thickness of the part of the second insulation layer 14 overlapping the hollow area 131 and the thickness of the part of the second insulation layer 14 overlapping the non-hollow area 132 is less than a preset value. The preset value may be the thickness of the first insulation layer, i.e., 0.05 μm to 0.15 μm. After forming a first insulation layer having hollow areas and a non-hollow area, an uneven step structure is obtained, and the first insulation layer can be filled by disposing the second insulation layer, thereby further improving the flatness of the display panel.

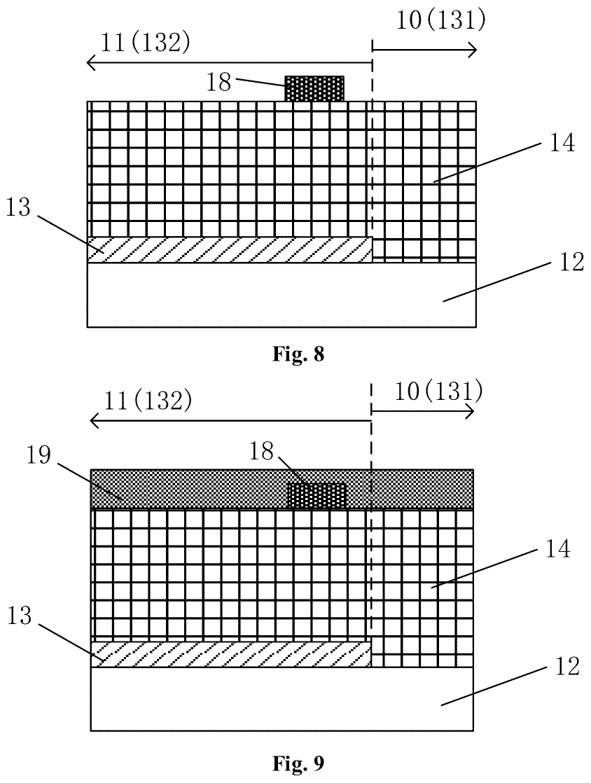

In another specific embodiment, as shown in FIG. 8, the display panel further includes a touch signal line 18 disposed on the side of the second insulation layer 14 away from the substrate 12. The arrangement of the touch signal line 18 described above can further achieve the touch function of the display panel; and by sensing and responding to the touch input, users can further operate the display panel by directly touching the screen.

Specifically, the touch signal line is for transmitting a signal to a touch electrode; and in practical applications, the connection between the touch signal line and the touch electrode can be achieved by drilling a via.

In another specific embodiment, as shown in FIG. 9, the display panel further includes a sixth insulation layer 19 overlapping the hollow area 131 and the non-hollow area 132, and the thickness of the part of the sixth insulation layer 19 overlapping the hollow area 131 may be the same as or different from the thickness of the part of the sixth insulation layer 19 overlapping the non-hollow area 132. In addition, the sixth insulation layer 19 is disposed on the side of the second insulation layer 14 away from the substrate 12 and the side of the touch signal line 18 away from the substrate 12. Due to the touch signal line includes a plurality of touch electrodes, an uneven step structure may be formed, and the sixth insulation layer 19 can facilitate achieving electrical isolation between the touch signal lines, thereby further improving the stability of touch signal transmission and the touch effect of the display panel.

Specifically, the formation process of the display panel including the sixth insulation layer is as follows: providing a substrate; forming a first preliminary insulation layer on the surface of the side of the substrate; removing the part of the first preliminary insulation layer to form hollow areas, and forming a first insulation layer from the remaining first preliminary insulation layer to obtain a third preliminary structure; forming a second insulation layer on the exposed surface of the third preliminary structure; forming a touch signal line on the side of the second insulation layer away from the substrate; and forming a sixth insulation layer on the side of the touch signal line away from the substrate.

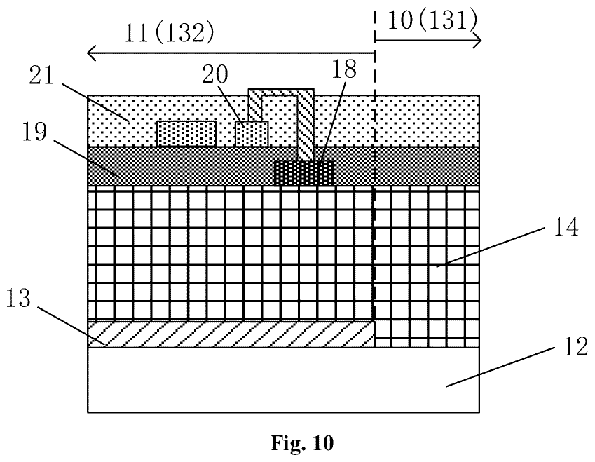

In another specific embodiment, as shown in FIG. 10, the display panel further includes a common electrode layer 20 disposed on the side of the sixth insulation layer 19 away from the second insulation layer 14, the common electrode layer 20 includes a plurality of common electrodes, and at least one of the common electrodes also serves as a touch electrode. In a display stage, the above-described common electrode layer 20 can provide an electric field, and the common electrode can apply a data voltage for displaying an image to control partial liquid crystal of each sub-pixel unit to deflect, thereby achieving image display. In a touch phase, a touch signal is applied to the common electrode, thereby achieving touch control.

In another specific embodiment, as shown in FIGS. 10 to 14, the display panel further includes a seventh insulation layer 21 overlapping the hollow area 131 and the non-hollow area 132, and the thickness of the part of the seventh insulation layer 21 overlapping the hollow area 131 may be the same as or different from the thickness of the part of the seventh insulation layer 21 overlapping the non-hollow area 132. The seventh insulation layer 21 is disposed on the side of the sixth insulation layer 19 and the touch signal line 18 away from the second insulation layer 14 and on the side of the common electrode layer 20 away from the sixth insulation layer 19. The seventh insulation layer 21 can facilitate achieving electrical isolation between the common electrodes, thereby further improving the touch effect of the display panel.

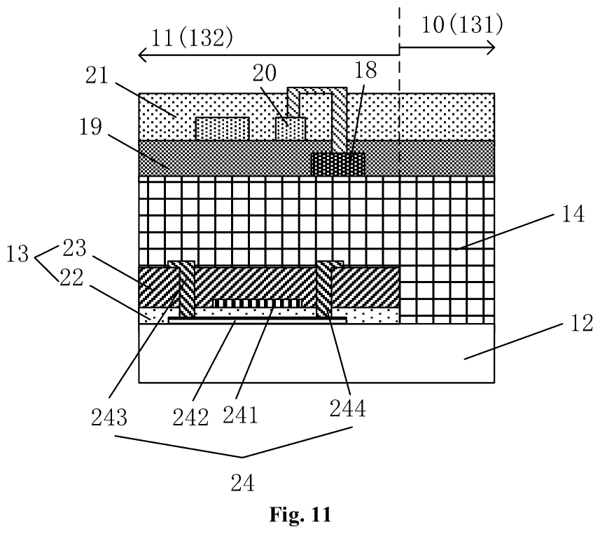

In another specific embodiment, as shown in FIG. 11, the first insulation layer 13 is disposed on the side of the sixth insulation layer 19 and the touch signal line 18 close to the substrate 12, and the first insulation layer 13 includes an eighth insulation layer 22 and a ninth insulation layer 23 that are disposed adjacent to each other. Since the material of the first insulation layer 13 is inorganic, the materials of the eighth insulation layer 22 and the ninth insulation layer 23 are inorganic. The common electrode layer 20 is disposed on the side of the sixth insulation layer 19 away from the second insulation layer 14. The above-described arrangement of the eighth insulation layer 22 and the ninth insulation layer 23 can further achieve the protection of devices.

Specifically, the materials of the eighth insulation layer and the ninth insulation layer may be at least one of silicon oxide or silicon nitride.

In a specific embodiment, as shown in FIG. 11, the display panel further includes a thin film transistor 24 disposed on the side of the substrate 12; the thin film transistor 24 includes a gate electrode 241, an active layer 242, a source electrode 243, and a drain electrode 244; the thin film transistor 24 may have a bottom gate structure or a top gate structure; and the thin film transistor 24 may be a low-temperature polysilicon thin film transistor or an oxide semiconductor thin film transistor. The gate electrode 241 is disposed at the side of the substrate 12, the active layer 242 is disposed at the side of the gate electrode 241 close to the substrate 12, the source electrode 243 and the drain electrode 244 are disposed at two ends of the active layer 242 respectively, the eighth insulation layer 22 is disposed between the gate electrode 241 and the active layer 242, and the ninth insulation layer 23 is disposed on the side of the gate electrode 241 away from the substrate 12 and the side of the eighth insulation layer 22 away from the substrate 12. The eighth insulation layer 22 may serve as a gate insulation layer to prevent a current from directly flowing from the gate electrode 241 to the source electrode 243 or the drain electrode 244, while allowing an electric field to act on the semiconductor layer, thereby controlling the conductance state of the channel region and further improving the overall performance of the thin film transistor 24. The ninth insulation layer 23 can serve as an interlayer insulation layer to achieve insulation between metals inside devices, thereby further improving the performance of the display panel.

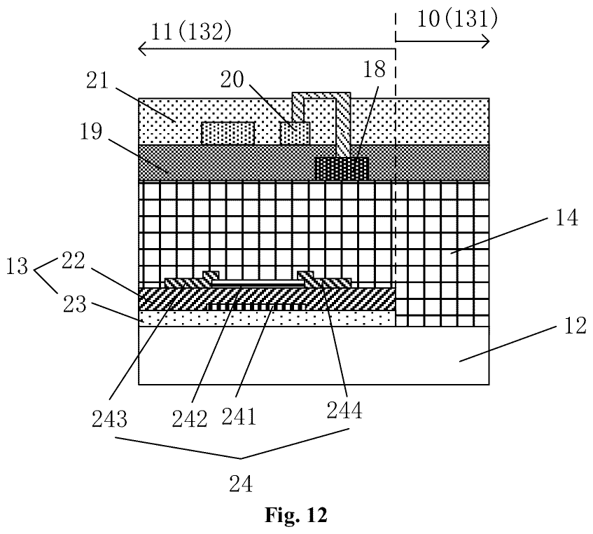

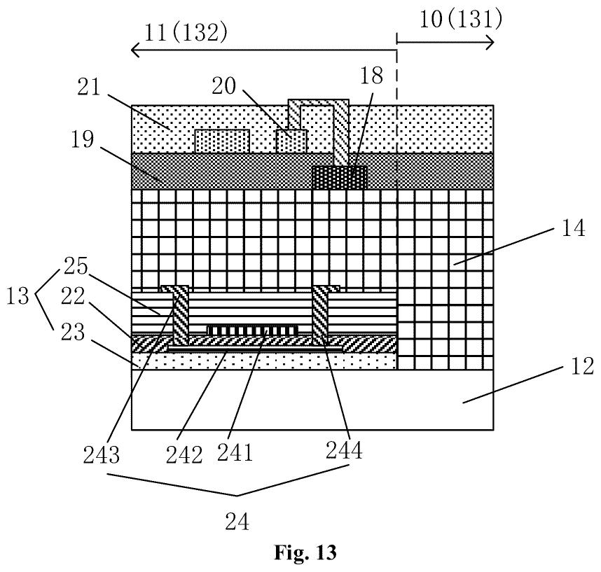

In some embodiments, as shown in FIG. 12, the display panel further includes a thin film transistor 24 disposed on the side of the substrate 12; the thin film transistor 24 includes a gate electrode 241, an active layer 242, a source electrode 243, and a drain electrode 244; the thin film transistor 24 may have a bottom gate structure or a top gate structure; and the thin film transistor 24 may be a low-temperature polysilicon thin film transistor or an oxide semiconductor thin film transistor. The gate electrode 241 is disposed at the side of the substrate 12; the active layer 242 is disposed above the gate electrode 241 away from the substrate 12; the source electrode 243 and the drain electrode 244 are disposed at two ends of the active layer 242 respectively; the eighth insulation layer 22 is disposed between the gate electrode 241 and the active layer 242; and the ninth insulation layer 23 is disposed at the side of the active layer 242 close to the substrate 12. The first insulation layer 13 is disposed at the side of the sixth insulation layer 19 and the touch signal line 18 close to the substrate 12, and the common electrode layer 20 is disposed on the side of the sixth insulation layer 19 away from the second insulation layer 14. The eighth insulation layer 22 may serve as a gate insulation layer to prevent a current from directly flowing from the gate electrode 241 to the source electrode 243 or the drain electrode 244, while allowing an electric field to act on the semiconductor layer, thereby controlling the conductance state of the channel region and further improving the overall performance of the thin film transistor 24. The above-described ninth insulation layer 23 can serve as a buffer layer to alleviate stress caused by the lattice constant mismatch between the substrate 12 and the first insulation layer 13 or the second insulation layer 14, thereby further improving the performance of the display panel.

In some embodiments, as shown in FIG. 13, the first insulation layer further includes a tenth insulation layer 25, and the tenth insulation layer 25 is disposed on the side of the gate electrode 241 away from the substrate 12. The tenth insulation layer 25 described above can serve as an interlayer insulation layer to achieve insulation between metals inside devices and reduce parasitic capacitance between the metal material and the substrate 12, thereby further improving the performance of the display panel. The thin film transistor 24 includes a gate electrode 241, an active layer 242, a source electrode 243, and a drain electrode 244; the eighth insulation layer 22 may serve as a gate insulation layer to prevent a current from directly flowing from the gate electrode 241 to the source electrode 243 or the drain electrode 244, while allowing an electric field to act on the semiconductor layer, thereby controlling the conductance state of the channel region and further improving the overall performance of the thin film transistor 24. The first insulation layer 13 is disposed at the side of the sixth insulation layer 19 and the touch signal line 18 close to the substrate 12, and the common electrode layer 20 is disposed on the side of the sixth insulation layer 19 away from the second insulation layer 14. The ninth insulation layer 23 may serve as a buffer layer or an interlayer insulation layer; as a buffer layer, the ninth insulation layer 23 can alleviate the stress caused by the lattice constant mismatch between the substrate 12 and the first insulation layer 13 or the second insulation layer 14, and the performance of the display panel can be further improved; and as an interlayer insulation layer, the ninth insulation layer 23 may achieve insulation between metals inside devices, thereby further improving the performance of the display panel.

Specifically, since the material of the first insulation layer is an inorganic material, the material of the tenth insulation layer is an inorganic material.

In some embodiments, as shown in FIG. 13, the source electrode 243 at least includes a first connection portion, the drain electrode 244 at least includes a second connection portion, the ends of the first connection portion and the second connection portion each are connected to the active layer 242, the first insulation layer 13 includes a first via and a second via, the first connection portion is disposed at least in the first via, and the second connection portion is disposed at least in the second via. The source electrode 243 and the drain electrode 244 are connected to the active layer through the first via and the second via respectively.

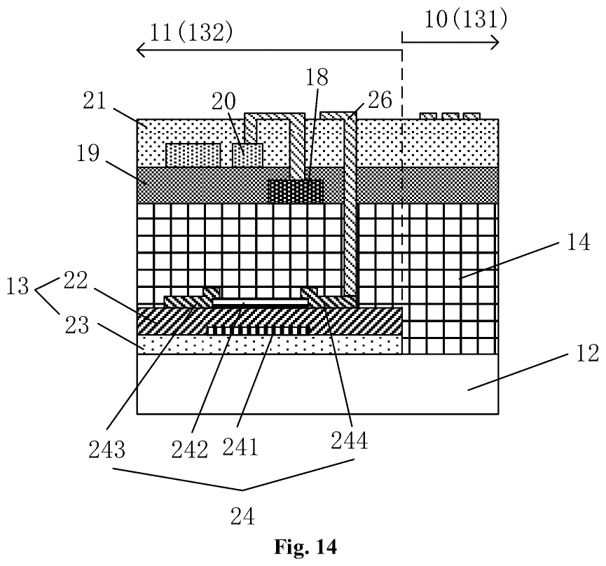

In some embodiments, as shown in FIG. 14, the display panel further includes a pixel electrode layer 26 disposed on the side of the thin film transistor 24 away from the substrate 12, the thin film transistor 24 includes a gate electrode 241, an active layer 242, a source electrode 243, and a drain electrode 244, and the first insulation layer 13 includes an eighth insulation layer 22 and a ninth insulation layer 23 that are disposed adjacent to each other. The pixel electrode layer 26 includes a plurality of pixel electrodes arranged at intervals, and the pixel electrodes are each electrically connected to the source electrode 243 or the drain electrode 244. The pixel electrode layer 26 is for driving the thin film transistor 24 to further achieve the display of images.

Specifically, the pixel electrode layer may be made of a transparent conductive material such as indium tin oxide. In practical applications, pixel electrodes and thin film transistors form a matrix structure, each thin film transistor corresponds to a corresponding sub-pixel to control the color and brightness of each pixel, and the pixel electrode is responsible for controlling the charging and discharging process of the corresponding thin film transistor.

### Comparative Example 1

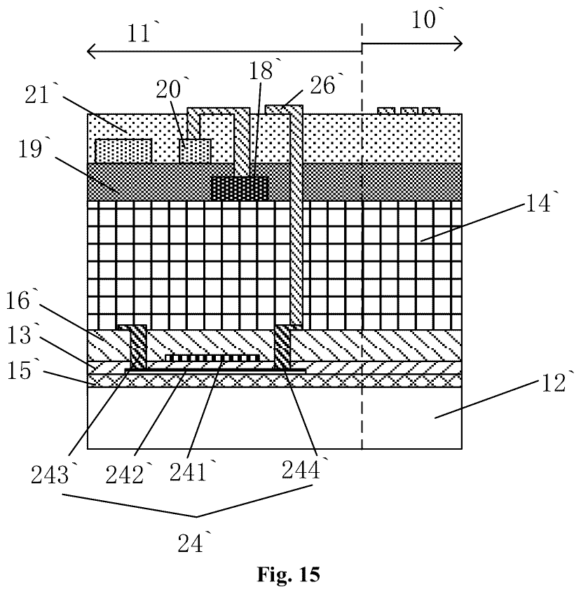

The present embodiment provides a display panel. As shown in FIG. 15, the display panel comprises opening areas 10′ and a non-opening area 11′, and the display panel further comprises:
a substrate 12′;
a first insulation layer 13′ disposed at a side of the substrate 12′, wherein the first insulation layer 13′ is disposed in the opening area 10′ and the non-opening area 11′ and between a third insulation layer 15′ and a fourth insulation layer 16′;
a second insulation layer 14′ disposed on the side of the first insulation layer 13′ away from the substrate 12′;
a thin film transistor 24′ disposed at the side of the substrate 12′, wherein the thin film transistor 24′ comprises a gate electrode 241′, an active layer 242′, a source electrode 243′, and a drain electrode 244′;
a touch signal line 18′ disposed on the side of the second insulation layer 14′ away from the substrate 12′ and comprising a plurality of touch electrodes;
a sixth insulation layer 19′ disposed in the opening area 10′ and the non-opening area 11′, wherein the sixth insulation layer 19′ is disposed on the side of the second insulation layer 14′ away from the substrate 12′ and the side of the touch signal line 18′ away from the substrate 12′;
a common electrode layer 20′ disposed on the side of the sixth insulation layer 19′ away from the second insulation layer 14′ and comprising a plurality of common electrodes, wherein at least one of the common electrodes also serves as a touch electrode;
a seventh insulation layer 21′ disposed on the side of the sixth insulation layer 19′ away from the second insulation layer 14′ and on the side of the common electrode layer 20′ away from the sixth insulation layer 19′; and
a pixel electrode layer 26′ disposed on the side of the thin film transistor 24′ away from the substrate 12′ and comprising a plurality of pixel electrodes arranged at intervals, and the pixel electrodes are each electrically connected to the source electrode 243′ or the drain electrode 244′.

### Embodiment 1

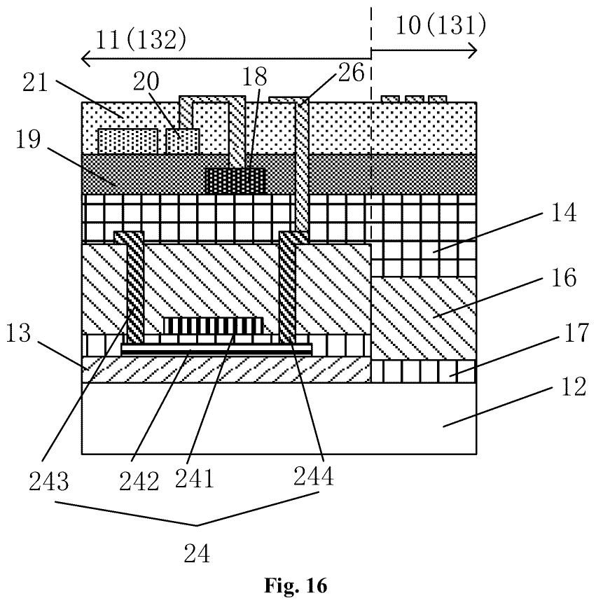

The present embodiment provides a display panel. As shown in FIG. 16, the display panel comprises opening areas 10 and a non-opening area 11, and the display panel further comprises:
a substrate 12;
a first insulation layer 13 disposed between the substrate 12 and the fifth insulation layer 17, wherein the first insulation layer 13 has hollow areas 131 and a non-hollow area 132, the hollow area 131 is disposed at a side of the non-hollow area 132 and at least partially overlaps the opening area 10, and the material of the first insulation layer 13 is an inorganic material;
a second insulation layer 14 disposed above the side of the first insulation layer 13 away from the substrate 12;
a fourth insulation layer 16 overlapping the hollow area 131 and the non-hollow area 132, and disposed between the substrate 12 and the second insulation layer 14, wherein a fourth insulation layer 16 is an interlayer insulation layer;
a fifth insulation layer 17 overlapping the hollow area 131 and the non-hollow area 132 and between the substrate 12 and the fourth insulation layer 16, wherein the fifth insulation layer 17 is a gate insulation layer;
a thin film transistor 24 disposed on the side of the substrate 12 and comprising a gate electrode 241, an active layer 242, a source electrode 243, and a drain electrode 244;
a touch signal line 18 disposed on the side of the second insulation layer 14 away from the substrate 12 and comprising a plurality of touch electrodes;
a sixth insulation layer 19 overlapping the hollow area 131 and the non-hollow area 132 and on the side of the second insulation layer 14 away from the substrate 12 and on the side of the touch signal line 18 away from the substrate 12;
a common electrode layer 20 disposed on the side of the sixth insulation layer 19 away from the second insulation layer 14 and comprising a plurality of common electrodes, wherein at least one of the common electrodes also serves as a touch electrode;
a seventh insulation layer 21 disposed on the side of the sixth insulation layer 19 away from the second insulation layer 14 and the side of the common electrode layer 20 away from the sixth insulation layer 19; and
the pixel electrode layer 26 disposed on the side of the thin film transistor 24 away from the substrate 12 and comprising a plurality of pixel electrodes arranged at intervals, wherein the pixel electrodes are each electrically connected to the source electrode 243 or the drain electrode 244.

### Embodiment 2

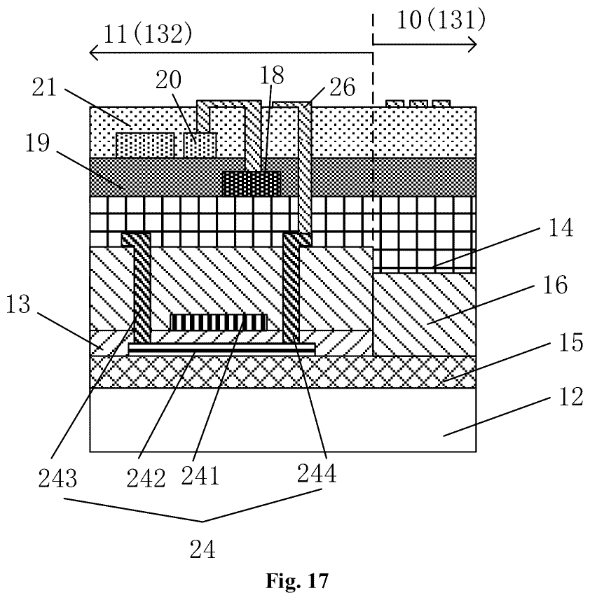

The present embodiment provides a display panel. As shown in FIG. 17, the display panel comprises opening areas 10 and a non-opening area 11, and the display panel further comprises:
a substrate 12;
a first insulation layer 13 disposed on a side of the substrate 12, wherein the first insulation layer 13 has hollow areas 131 and a non-hollow area 132, the hollow area 131 is disposed at a side of the non-hollow area 132, the hollow area 131 at least partially overlaps the opening area 10, the material of the first insulation layer 13 is silicon oxide, the first insulation layer 13 is a gate insulation layer, and the first insulation layer 13 is disposed between the third insulation layer 15 and the fourth insulation layer 16;
a second insulation layer 14 disposed above the side of the first insulation layer 13 away from the substrate 12;
a third insulation layer 15 overlapping the hollow area 131 and the non-hollow area 132, and disposed between the substrate 12 and the second insulation layer 14 and between the substrate 12 and the first insulation layer 13;
a fourth insulation layer 16 overlapping the hollow area 131 and the non-hollow area 132, wherein the fourth insulation layer 16 is disposed between the substrate 12 and the second insulation layer 14, and the fourth insulation layer 16 is an interlayer insulation layer;
a thin film transistor 24 disposed on the side of the substrate 12 and comprising a gate electrode 241, an active layer 242, a source electrode 243, and a drain electrode 244;
a touch signal line 18 disposed on the side of the second insulation layer 14 away from the substrate 12 and comprising a plurality of touch electrodes;
a sixth insulation layer 19 overlapping the hollow area 131 and the non-hollow area 132, disposed on the side of the second insulation layer 14 away from the substrate 12 and on the side of the touch signal line 18 away from the substrate 12;
a common electrode layer 20 disposed on the side of the sixth insulation layer 19 away from the second insulation layer 14 and comprising a plurality of common electrodes, wherein at least one of the common electrodes also serves as a touch electrode;
a seventh insulation layer 21 disposed on the side of the sixth insulation layer 19 away from the second insulation layer 14 and the side of the common electrode layer 20 away from the sixth insulation layer 19; and
the pixel electrode layer 26 disposed on the side of the thin film transistor 24 away from the substrate 12 and comprising a plurality of pixel electrodes arranged at intervals, wherein the pixel electrodes are each electrically connected to the source electrode 243 or the drain electrode 244.

### Embodiment 3

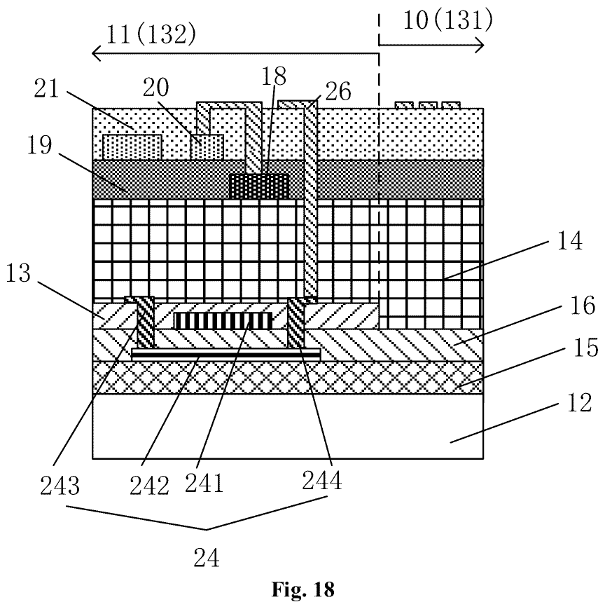

The present embodiment provides a display panel. As shown in FIG. 18, the display panel comprises opening areas 10 and a non-opening area 11, and the display panel further comprises:
a substrate 12;
a first insulation layer 13 disposed on a side of the substrate 12, wherein the first insulation layer 13 has hollow areas 131 and a non-hollow area 132, the hollow area 131 is disposed at a side of the non-hollow area 132, the hollow area 131 at least partially overlaps the opening area 10, the material of the first insulation layer 13 is silicon nitride, the first insulation layer 13 is an interlayer insulation layer, and the first insulation layer 13 is disposed between the fourth insulation layer 16 and the second insulation layer 14;
a second insulation layer 14 disposed above the side of the first insulation layer 13 away from the substrate 12;
a third insulation layer 15 overlapping the hollow area 131 and the non-hollow area 132, and disposed between the substrate 12 and the second insulation layer 14 and between the substrate 12 and the first insulation layer 13;
a fourth insulation layer 16 overlapping the hollow area 131 and the non-hollow area 132, wherein the fourth insulation layer 16 is disposed between the substrate 12 and the second insulation layer 14, and the fourth insulation layer 16 is a gate insulation layer;
a thin film transistor 24 disposed on the side of the substrate 12 and comprising a gate electrode 241, an active layer 242, a source electrode 243, and a drain electrode 244;
a touch signal line 18 disposed on the side of the second insulation layer 14 away from the substrate 12 and comprising a plurality of touch electrodes;
a sixth insulation layer 19 overlapping the hollow area 131 and the non-hollow area 132, and disposed on the side of the second insulation layer 14 away from the substrate 12 and on the side of the touch signal line 18 away from the substrate 12;
a common electrode layer 20 disposed on the side of the sixth insulation layer 19 away from the second insulation layer 14 and comprising a plurality of common electrodes, wherein at least one of the common electrodes also serves as a touch electrode;
a seventh insulation layer 21 disposed on the side of the sixth insulation layer 19 away from the second insulation layer 14 and the side of the common electrode layer 20 away from the sixth insulation layer 19; and
a pixel electrode layer 26 disposed on the side of the thin film transistor 24 away from the substrate 12 and comprising a plurality of pixel electrodes arranged at intervals, wherein the pixel electrodes are each electrically connected to the source electrode 243 or the drain electrode 244.

### Embodiment 4

The present embodiment provides a display panel, as shown in FIG. 18, the display panel of the present embodiment is different from Embodiment 3 in that: the material of the first insulation layer 13 is silicon oxide.

### Embodiment 5

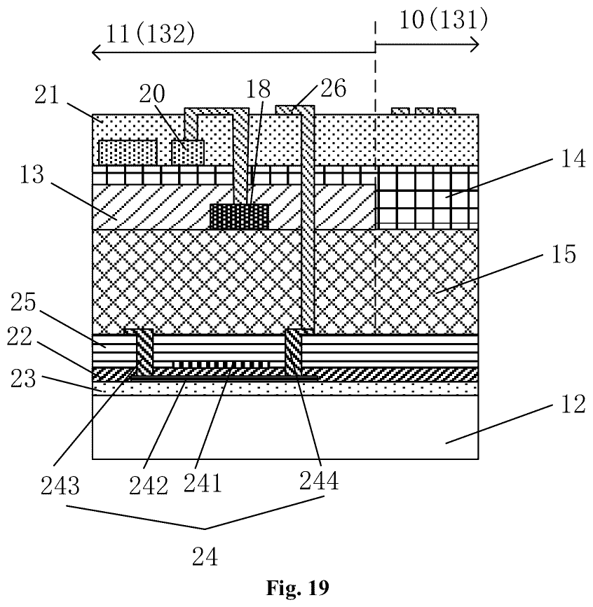

The present embodiment provides a display panel. As shown in FIG. 19, the display panel comprises opening areas 10 and a non-opening area 11, and the display panel further comprises:
a substrate 12;
a thin film transistor 24 disposed on a side of the substrate 12 and comprising a gate electrode 241, an active layer 242, a source electrode 243, and a drain electrode 244, wherein an eighth insulation layer 22 is disposed between a ninth insulation layer 23 and a tenth insulation layer 25;
a first insulation layer 13 disposed on the side of the substrate 12, wherein the first insulation layer 13 has hollow areas 131 and a non-hollow area 132, the hollow area 131 is disposed at a side of the non-hollow area 132, the hollow area 131 at least partially overlaps the opening area 10, the material of the first insulation layer 13 is silicon nitride, the first insulation layer 13 is disposed between the second insulation layer 14 and the third insulation layer 15, wherein the first insulation layer 13 serves as an insulation layer of the pixel electrode layer 26;
a second insulation layer 14 disposed above the side of the first insulation layer 13 away from the substrate 12;
a third insulation layer 15 overlapping the hollow area 131 and the non-hollow area 132, and disposed between the substrate 12 and the second insulation layer 14 and between the substrate 12 and the first insulation layer 13;
a touch signal line 18 disposed on the side of the second insulation layer 14 away from the substrate 12 and comprising a plurality of touch electrodes;
a common electrode layer 20 disposed on the side of the second insulation layer 14 away from the first insulation layer 13 and comprising a plurality of common electrodes, wherein at least one of the common electrodes also serves as a touch electrode;
a seventh insulation layer 21 disposed on the side of the second insulation layer 14 away from the first insulation layer 13 and the side of the common electrode layer 20 away from the second insulation layer 14; and
a pixel electrode layer 26 disposed on the side of the thin film transistor 24 away from the substrate 12 and comprising a plurality of pixel electrodes arranged at intervals, wherein the pixel electrodes are each electrically connected to the source electrode 243 or the drain electrode 244.

### Embodiment 6

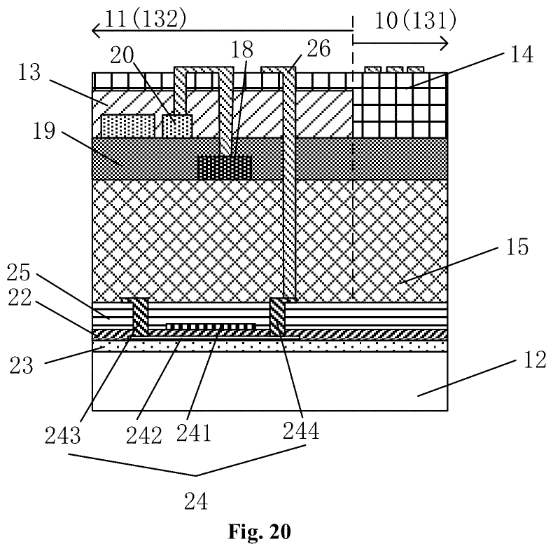

The present embodiment provides a display panel. As shown in FIG. 20, the display panel comprises opening areas 10 and a non-opening area 11, and the display panel further comprises:
a substrate 12;
a thin film transistor 24 disposed on a side of the substrate 12 and comprising a gate electrode 241, an active layer 242, a source electrode 243, and a drain electrode 244, wherein an eighth insulation layer 22 is disposed between a ninth insulation layer 23 and a tenth insulation layer 25;
a first insulation layer 13 disposed on the side of the substrate 12, wherein the first insulation layer 13 has hollow areas 131 and a non-hollow area 132, the hollow area 131 is disposed at a side of the non-hollow area 132, the hollow area 131 at least partially overlaps the opening area 10, the material of the first insulation layer 13 is silicon nitride, and the first insulation layer 13 is disposed between a second insulation layer 14 a the sixth insulation layer 19;
a second insulation layer 14 disposed above the side of the first insulation layer 13 away from the substrate 12;
a third insulation layer 15 overlapping the hollow area 131 and the non-hollow area 132, and disposed between the substrate 12 and the second insulation layer 14 and disposed between the substrate 12 and the first insulation layer 13;
a touch signal line 18 disposed on the side of the second insulation layer 14 away from the substrate 12 and comprising a plurality of touch electrodes;
a sixth insulation layer 19 overlapping the hollow area 131 and the non-hollow area 132, wherein the sixth insulation layer 19 is disposed on the side of the third insulation layer 15 away from the substrate 12 and on the side of the touch signal line 18 away from the substrate 12;
a common electrode layer 20 disposed on the side of the sixth insulation layer 19 away from the second insulation layer 14 and comprising a plurality of common electrodes, wherein at least one of the common electrodes also serves as a touch electrode; and
a pixel electrode layer 26 disposed on the side of the thin film transistor 24 away from the substrate 12 and comprising a plurality of pixel electrodes arranged at intervals, wherein the pixel electrodes are each electrically connected to the source electrode 243 or the drain electrode 244.

### Embodiment 7

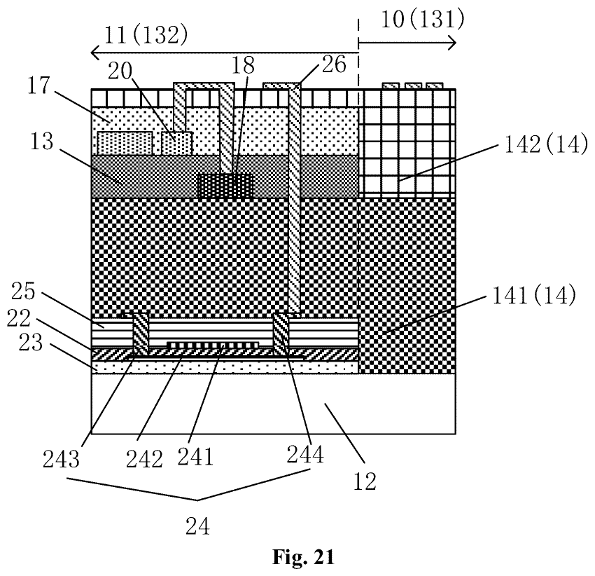

The present embodiment provides a display panel. As shown in FIG. 21, the display panel comprises opening areas 10 and a non-opening area 11, and the display panel further comprises:
a substrate 12;
a thin film transistor 24 disposed on a side of the substrate 12 and comprising a gate electrode 241, an active layer 242, a source electrode 243, and a drain electrode 244, wherein an eighth insulation layer 22 is disposed between a ninth insulation layer 23 and a tenth insulation layer 25;
a first insulation layer 13 disposed on the side of the substrate 12, wherein the first insulation layer 13 has hollow areas 131 and a non-hollow area 132, the hollow area 131 is disposed at a side of the non-hollow area 132, the hollow area 131 at least partially overlaps the opening area 10, the material of the first insulation layer 13 is silicon nitride, the first insulation layer 13 is an interlayer insulation layer, and the first insulation layer 13 is disposed between a first sub-insulation layer 141 and a fifth insulation layer 17;
a second insulation layer 14 comprising the first sub-insulation layer 141 and a second sub-insulation layer 142, wherein the first sub-insulation layer 141 is disposed on the side of the thin film transistor 24 away from the substrate 12 and on a portion of the surface of the substrate 12, and the second sub-insulation layer 142 is disposed on the surface of the fifth insulation layer 17 away from the first insulation layer 13 and on a portion of the surface of the first sub-insulation layer 141 away from the substrate 12;
a touch signal line 18 disposed on the side of the second insulation layer 14 away from the substrate 12 and comprising a plurality of touch electrodes;
a common electrode layer 20 disposed on the side of the first insulation layer 13 away from the first sub-insulation layer 141 and comprising a plurality of common electrodes, wherein at least one of the common electrodes also serves as a touch electrode; and
a pixel electrode layer 26 disposed on the side of the thin film transistor 24 away from the substrate 12 and comprising a plurality of pixel electrodes arranged at intervals, wherein the pixel electrodes are each electrically connected to the source electrode 243 or the drain electrode 244.

### Embodiment 8

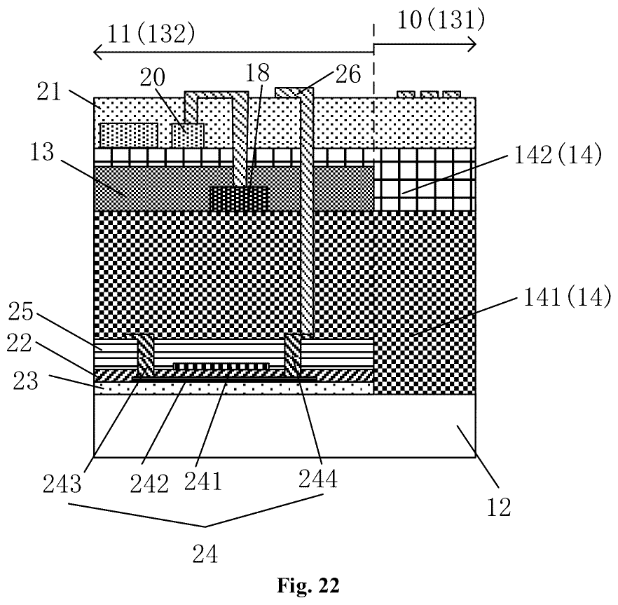

The present embodiment provides a display panel. As shown in FIG. 22, the display panel comprises opening areas 10 and a non-opening area 11, and the display panel further comprises:
a substrate 12;
a thin film transistor 24 disposed on a side of the substrate 12 and comprising a gate electrode 241, an active layer 242, a source electrode 243, and a drain electrode 244, wherein an eighth insulation layer 22 is disposed between a ninth insulation layer 23 and a tenth insulation layer 25;
a first insulation layer 13 disposed on the side of the substrate 12, wherein the first insulation layer 13 has hollow areas 131 and a non-hollow area 132, the hollow area 131 is disposed at a side of the non-hollow area 132, the hollow area 131 at least partially overlaps the opening area 10, the material of the first insulation layer 13 is silicon nitride, the first insulation layer 13 is an interlayer insulation layer, and the first insulation layer 13 is disposed between a first sub-insulation layer 141 and a second sub-insulation layer 142;
a second insulation layer 14 comprising the first sub-insulation layer 141 and the second sub-insulation layer 142, wherein the first sub-insulation layer 141 is disposed on the side of the thin film transistor 24 away from the substrate 12 and on a portion of the surface of the substrate 12, and the second sub-insulation layer 142 is disposed on the surface of the first insulation layer 13 away from the first sub-insulation layer 141 and on a portion of the surface of the first sub-insulation layer 141 away from the substrate 12;
a touch signal line 18 disposed on the side of the second insulation layer 14 away from the substrate 12 and comprising a plurality of touch electrodes;
a common electrode layer 20 disposed on the side of the first insulation layer 13 away from the first sub-insulation layer 141 and comprising a plurality of common electrodes, wherein at least one of the common electrodes also serves as a touch electrode; and
a seventh insulation layer 21 disposed on the side of the second sub-insulation layer 142 away from the first insulation layer 13 and the side of the common electrode layer 20 away from the second sub-insulation layer 142; and
a pixel electrode layer 26 disposed on the side of the thin film transistor 24 away from the substrate 12 and comprising a plurality of pixel electrodes arranged at intervals, wherein the pixel electrodes are each electrically connected to the source electrode 243 or the drain electrode 244.

### Embodiment 9

The present embodiment provides a display panel, as shown in FIG. 17, the display panel of the present embodiment is different from Embodiment 2 in that: the material of the first insulation layer 13 is silicon nitride.

The reflectivity and reflection hue of each of the display panels in the Embodiments 1 to 8 and Comparative Example 1 are tested, wherein the thin film transistors in the display panels each were a low-temperature polysilicon transistor; and the test results are shown in Table 1, wherein the reflectivity change value is the reflectivity change difference of the display panel, and Δa* and Δb* are chromaticity coordinates, which are optical parameters for representing the reflection hue, and the closer the value of the reflection hue is to 0, the smaller the reflection hue difference.

TABLE 1

| | Reflectivity change value | Δa* | Δb* |
|---|---|---|---|
| Comparative example 1 | 11.8% | 0.35 | −4.08 |
| Embodiment 6 | −13.3% | 12.38 | −20.03 |
| Embodiment 5 | −9.4% | −5.33 | 1.90 |
| Embodiment 4 | −3.8% | −0.01 | −1.11 |
| Embodiment 3 | −15.2% | 0.07 | −1.54 |
| Embodiment 2 | −4.0% | 0.11 | 0.04 |
| Embodiment 1 | 3.7% | −0.18 | 0.95 |
| Embodiment 7 | −28.9% | 24.45 | −31.92 |
| Embodiment 8 | −25.6% | −6.27 | 0.46 |

The reflectivity and reflection hue of each of the display panels in the Embodiments 2 to 4, Embodiments 6 to 9, and Comparative Example 1 are tested, wherein the thin film transistors in the display panels each are a back channel etch (BCE) type thin film transistor, and the test results are shown in Table 2.

TABLE 2

| | Reflectivity change value | Δa* | Δb* |
|---|---|---|---|
| Comparative example 1 | 9.5% | 0.27 | −11.61 |
| Embodiment 6 | 37.3% | −23.69 | 4.36 |
| Embodiment 3 | −0.5% | −1.71 | 3.10 |
| Embodiment 4 | 1.4% | −0.24 | −0.09 |
| Embodiment 2 | −2.1% | 0.41 | −1.08 |
| Embodiment 9 | −6.6% | 7.22 | 1.20 |
| Embodiment 7 | 30.2% | −18.78 | 7.42 |
| Embodiment 8 | −8.5% | 5.97 | 3.89 |

The reflectivity and reflection hue of each of the display panels in the Embodiments 2 to 9 and Comparative Example 1, wherein the thin film transistors in the display panels each are a thin film transistor of a type having an etch stop layer (ESL) are tested, and the test results are shown in Table 3.

TABLE 3

| | Reflectivity change value | Δa* | Δb* |
|---|---|---|---|
| Comparative example 1 | 9.2% | −13.90 | −1.86 |
| Embodiment 6 | −6.1% | −2.78 | −3.34 |
| Embodiment 5 | 4.9% | 4.38 | −1.79 |
| Embodiment 3 | −4.5% | 0.77 | −1.16 |
| Embodiment 4 | −3.8% | 1.07 | −0.98 |
| Embodiment 2 | −5.2% | 0.33 | −0.62 |
| Embodiment 9 | −11.4% | 11.98 | −3.68 |
| Embodiment 7 | −14.3% | 0.46 | 0.42 |
| Embodiment 8 | −13.7% | 17.59 | −3.04 |

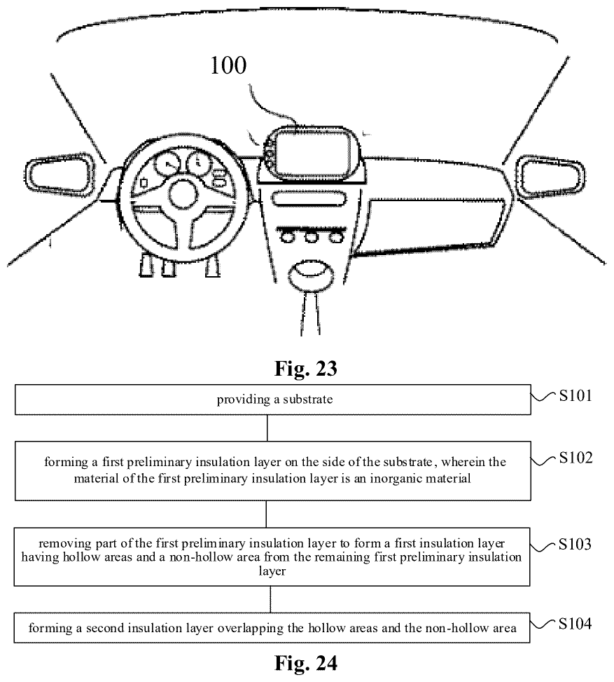

In still another typical embodiment, as shown in FIG. 23, the present application provides a display apparatus comprising any one of the above-described display panels 100. The specific structure of the display panel 100 is described in detail in the above-described embodiments, and will not be repeated here. Of course, the display apparatus shown in FIG. 17 is merely for schematic description, and may be a vehicle-mounted display apparatus as shown in FIG. 17, or any electronic device having a display function such as a mobile phone, a tablet computer, a notebook computer, an electronic book, or a television.

Since the display apparatus provided in embodiments of the present application comprising the above-described display panel, and thus the structures of a portion corresponding to opening areas and a portion corresponding to a non-opening area in the display panel are separately designed, the opening areas correspond to hollow areas of the first insulation layer, and the second insulation layer is arranged in the hollow area, and due to the material of the first insulation layer is an inorganic material, and the material of the second insulation layer is an organic material, the original inorganic material is replaced with the organic material, which can reduce the number of optical interfaces in the opening area. In addition, since the non-opening area corresponds to the non-hollow area of the first insulation layer, the reflectivity is reduced without affecting the original film layer structure of the non-opening area of the display panel, and the transmittance of the display panel is improved, thereby solving the technical problem with how to increase the transmittance of the display panel in the prior art.

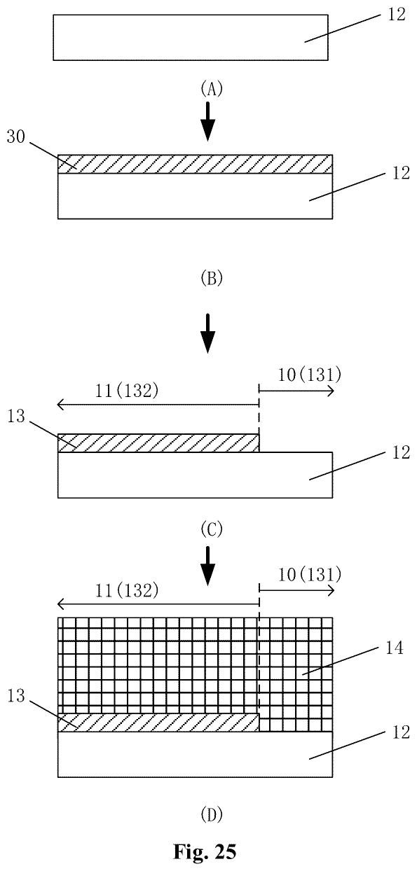

In another typical embodiment, the present application provides a method for manufacturing a display panel, wherein the display panel comprises opening areas 10 and a non-opening area 11. As shown in FIG. 24, the method includes:
Step S101, providing a substrate 12 to obtain the structure shown in the sectional diagram (A) shown in FIG. 25;
Step S102, forming a first preliminary insulation layer 30 on the side of the substrate 12, wherein the material of the first preliminary insulation layer 30 is an inorganic material to obtain the structure shown in the sectional diagram (B) shown in FIG. 25;
Step S103, removing part of the first preliminary insulation layer 30, and forming a first insulation layer 13 having hollow areas 131 and a non-hollow area 132 from the remaining first preliminary insulation layer 30 to obtain the structure shown in the sectional diagram (C) shown in FIG. 25, the hollow area 131 at least partially overlapping the opening area 10; and
Step S104, forming a second insulation layer overlapping the hollow areas 131 and the non-hollow area 132 to obtain the structure shown in the sectional diagram (D) shown in FIG. 25, the material of the second insulation layer 14 being an organic material.

Embodiments of the present application provide a method for manufacturing a display panel; the structures of a portion corresponding to opening areas and a portion corresponding to a non-opening area in the display panel are separately designed; the opening areas correspond to hollow areas of the first insulation layer, and the second insulation layer is arranged in the hollow area; and due to the material of the first insulation layer is an inorganic material, and the material of the second insulation layer is an organic material, the original inorganic material is replaced with the organic material, which can reduce the number of optical interfaces in the opening area. In addition, since the non-opening area corresponds to the non-hollow area of the first insulation layer, the reflectivity is reduced without affecting the original film layer structure of the non-opening area of the display panel, and the transmittance of the display panel is improved, thereby solving the technical problem with how to increase the transmittance of the display panel in the prior art.

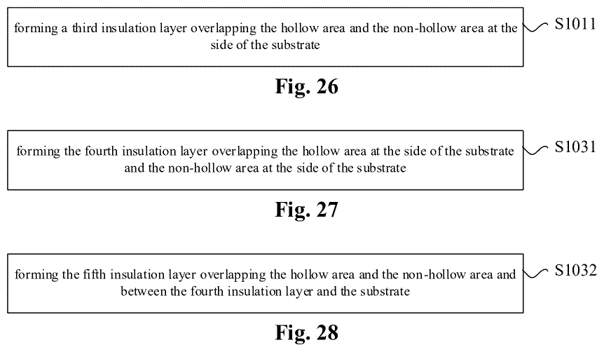

In still another specific embodiment, as shown in FIG. 26, after the step S101 and before the step S102, the method further comprises: Step S1011, forming a third insulation layer 15 on the side of the substrate 12 overlapping the hollow area 131 and the non-hollow area 132 to obtain the structure shown in FIG. 4. The method can further quickly form the third insulation layer.

Specifically, the material of the third insulation layer is different from the material of the second insulation layer, and the material of the third insulation layer may be silicon nitride.

In another specific embodiment, as shown in FIG. 27, after the step S103 and before the step S104, the method further comprises: Step S1031, forming the fourth insulation layer 16 overlapping the hollow area 131 at the side of the substrate 12 and the non-hollow area 132 on the side of the substrate 12 to obtain the structure shown in FIG. 5. The method can further quickly form the fourth insulation layer.

Specifically, the material of the fourth insulation layer is different from the material of the second insulation layer, and the material of the fourth insulation layer may be silicon nitride.

In still another specific embodiment, as shown in FIG. 28, after the step S1031, the method further comprises: step S1032, forming the fifth insulation layer 17 overlapping the hollow area 131 and the non-hollow area 132 and between the fourth insulation layer 16 and the substrate 12 to obtain the structure shown in FIG. 6. The method can further quickly form the fifth insulation layer.

Specifically, the material of the fifth insulation layer is different from the material of the second insulation layer, and the material of the fourth insulation layer may be silicon oxide.

However, the above descriptions are merely the preferred embodiments of the present application and are not used for limiting the present application, and various modifications and variations may be made in the present application for those skilled in the art. Any modification, equivalent replacement and improvement made within the gist and principle of the present application shall be included in the protection scope of the present application.

What is claimed is:

1. A display panel comprising opening areas and a non-opening area, and further comprising:
a substrate;
a first insulation layer disposed on a side of the substrate, wherein
the first insulation layer has hollow areas and a non-hollow area, the hollow areas at least partially overlap the opening areas respectively, and a material of the first insulation layer is an inorganic material; and
a second insulation layer overlapping the hollow areas and the non-hollow area, wherein
a material of the second insulation layer is an organic material, and a thickness of part of the second insulation layer overlapping the non-hollow area is smaller than a thickness of part of the second insulation layer overlapping the hollow areas.

2. The display panel according to claim 1, wherein the second insulation layer is disposed above a side of the first insulation layer away from the substrate.

3. The display panel according to claim 1, further comprising:
a third insulation layer overlapping the hollow areas and the non-hollow area, and disposed between the substrate and the second insulation layer and between the substrate and the first insulation layer.

4. The display panel according to claim 1, further comprising:
a fourth insulation layer overlapping the hollow areas and the non-hollow area, and disposed between the substrate and the second insulation layer.

5. The display panel according to claim 4, further comprising:
a fifth insulation layer overlapping the hollow areas and the non-hollow area, and disposed between the substrate and the fourth insulation layer.

6. The display panel according to claim 1, wherein
a difference between the thickness of the part of the second insulation layer overlapping the hollow areas and the thickness of the part of the second insulation layer overlapping the non-hollow area is less than a preset value.

7. The display panel according to claim 1, further comprising:
a touch signal line disposed on a side of the second insulation layer away from the substrate.

8. The display panel according to claim 7, further comprising:
a sixth insulation layer overlapping the hollow areas and the non-hollow area, and disposed on the side of the second insulation layer away from the substrate and a side of the touch signal line away from the substrate.

9. The display panel according to claim 8, further comprising:
a common electrode layer disposed on a side of the sixth insulation layer away from the second insulation layer, wherein
the common electrode layer comprises a plurality of common electrodes, and at least one of the common electrodes also serves as a touch electrode.

10. The display panel according to claim 9, further comprising:
a seventh insulation layer disposed on a side of the sixth insulation layer away from the second insulation layer and a side of the common electrode layer away from the sixth insulation layer.

11. The display panel according to claim 8, wherein
the first insulation layer is disposed at a side of the sixth insulation layer close to the substrate, and the first insulation layer comprises an eighth insulation layer and a ninth insulation layer that are disposed adjacent to each other.

12. The display panel according to claim 11, further comprising:
a thin film transistor disposed on the side of the substrate and comprising:
a gate electrode,
an active layer,
a source electrode, and
a drain electrode,
wherein the gate electrode is disposed at the side of the substrate, the active layer is disposed at a side of the gate electrode close to the substrate, the source electrode and the drain electrode are disposed at two ends of the active layer respectively, the eighth insulation layer is disposed between the gate electrode and the active layer, and the ninth insulation layer is disposed on a side of the gate electrode away from the substrate and on a side of the eighth insulation layer away from the substrate.

13. The display panel according to claim 11, further comprising:
a thin film transistor disposed on the side of the substrate and comprising:
a gate electrode,
an active layer,
a source electrode, and
a drain electrode,
wherein the gate electrode is disposed at the side of the substrate, the active layer is disposed above the gate electrode away from the substrate, the source electrode and the drain electrode are disposed at two ends of the active layer respectively, the eighth insulation layer is disposed between the gate electrode and the active layer, and the ninth insulation layer is disposed at a side of the active layer close to the substrate.

14. The display panel according to claim 12, wherein
the source electrode at least comprises a first connection portion, the drain electrode at least comprises a second connection portion, an end of the first connection portion and an end of the second connection portion each are connected to the active layer, and the first insulation layer comprises a first via and a second via, the first connection portion is disposed at least in the first via, and the second connection portion is disposed at least in the second via.

15. The display panel according to claim 12, further comprising:
a pixel electrode layer disposed at a side of the thin film transistor away from the substrate, wherein the pixel electrode layer comprises a plurality of pixel electrodes arranged at intervals, and electrically connected to the source electrode or the drain electrode.

16. A display apparatus comprising a display panel comprising opening areas and a non-opening area, and further comprising:
a substrate;
a first insulation layer disposed on a side of the substrate, wherein
the first insulation layer has hollow areas and a non-hollow area, the hollow areas at least partially overlap the opening areas respectively, and a material of the first insulation layer is an inorganic material; and
a second insulation layer overlapping the hollow areas and the non-hollow area, wherein
a material of the second insulation layer is an organic material, and a thickness of part of the second insulation layer overlapping the non-hollow area is smaller than a thickness of part of the second insulation layer overlapping the hollow areas.

17. A method for manufacturing a display panel, wherein the display panel comprising opening areas and a non-opening area, and the method comprises:
providing a substrate;
forming a first preliminary insulation layer on a side of the substrate, wherein a material of the first preliminary insulation layer is an inorganic material;
removing part of the first preliminary insulation layer to form a first insulation layer having hollow areas and a non-hollow area from the remaining first preliminary insulation layer, the hollow area at least partially overlapping the opening area; and
forming a second insulation layer overlapping the hollow areas and the non-hollow area, a material of the second insulation layer being an organic material.

18. The method according to claim 17, wherein after the providing a substrate and before the forming a first preliminary insulation layer on a side of the substrate, the method further comprises:
forming a third insulation layer overlapping the hollow areas and the non-hollow area at the side of the substrate.

19. The method according to claim 18, wherein
after the removing part of the first preliminary insulation layer to form a first insulation layer having hollow areas and a non-hollow area from the remaining first preliminary insulation layer, and before the forming a second insulation layer in the hollow area and the non-hollow area, the method further comprises:
forming a fourth insulation layer overlapping the hollow areas and the non-hollow area at the side of the substrate.

20. The method according to claim 19, wherein after the forming a fourth insulation layer overlapping the hollow areas and the non-hollow area at the side of the substrate, the method comprises:
forming a fifth insulation layer overlapping the hollow areas and the non-hollow area and between the fourth insulation layer and the substrate.
